(19) United States
(12) Patent Application Publication
(10) Pub. No.: US 2025/0020714 A1
(43) Pub. Date: Jan. 16, 2025

(54) UNCERTAINTY ESTIMATION FOR A POSITION RECONSTRUCTION OF SEMICONDUCTOR COMPONENTS ON A WAFER

(71) Applicant: Robert Bosch GmbH, Stuttgart (DE)

(72) Inventors: Eric Sebastian Schmidt, Heimsheim (DE); Stefan Patrick Lindt, Ettlingen (DE)

(21) Appl. No.: 18/712,741

(22) PCT Filed: Feb. 6, 2023
(86) PCT No.: PCT/EP2023/052855

§ 371 Date: May 23, 2024

(30) Foreign Application Priority Data
Feb. 25, 2022 (DE) 10 2022 201 967.9

(51) Int. Cl. G01R 31/28; G06N 20/00

(52) U.S. Cl. CPC G01R 31/2884; G06N 20/00

(57) ABSTRACT

A method for estimating an uncertainty of an assignment rule that assigns first variables from a first set of first variables to second variables from a second set of second variables. The method includes: ascertaining inaccuracies of a machine learning system trained with the assignment rule, wherein the inaccuracies are ascertained by means of a difference between the second variables predicted by the machine learning system depending on the first variables and the second variables assigned to the first variables according to the assignment rule; ascertaining a covariance matrix depending on the ascertained inaccuracies; ascertaining a likelihood matrix and normalizing the likelihood matrix by dividing the value of the likelihood matrix by the corresponding column sum.

### FIELD

The present invention relates to a method for estimating an uncertainty of an assignment rule for a reconstruction of positions of semiconductor components on a wafer onto which the semiconductor components were applied, after the semiconductor components have been cut out of the wafer, and to a device configured to perform the method.

### BACKGROUND INFORMATION

In the packaging process of semiconductor components (specifically PowerMOS), traceability of the semiconductor components to their original wafer and their original position on the wafer is lost. Concretely, this means that the position of each semiconductor component on a wafer is no longer available once the wafer has been cut or diced (a method in which semiconductor components are separated from the wafer) and packaged. Providers of packaging processes are able to offer at least rough matching between loose semiconductor components in the final test (test process of the semiconductor components after packaging) and semiconductor components on the wafer in wafer level tests (test process before packaging). However, this still results in several thousand semiconductor components that cannot be assigned to several wafers. Since this is essentially a combinatorial problem, the complexity of achieving this task is factorial since there are n factorial different possibilities of arranging the semiconductor components such that they correspond to the correct order, where n is the number of semiconductor components.

For ASIC semiconductor components, there is a solution to this combinatorial problem. For this purpose, an unambiguous identifier is stored in the memory of the ASIC semiconductor components during the wafer level test, which makes assigning the final test to the wafer level test after packaging possible. However, for semiconductor components such as PowerMOS, this is not possible due to a lack of memory.

German Patent Application No. DE 10 2021 209 343, which is not pre-published, describes a method for ascertaining an assignment rule between semiconductor components depending on results of the wafer level test and packaged semiconductor components depending on results of the final test.

### SUMMARY

The present invention may have the advantage of making it possible to output a probabilistic statement with regard to a reliability of this assignment rule, without the need for added metadata, such as unambiguous identifiers or the like.

The present invention furthermore may have the advantage that this ascertained reliability is used to make better process control of the production (e.g., root cause analysis of defect parts) possible.

Aspects, developments, and example embodiments of the present invention are disclosed herein.

In a first aspect, the present invention relates to an, in particular computer-implemented, method for estimating an uncertainty of an assignment rule that assigns first variables from a first set of first variables to second variables from a second set of second variables. According to an example embodiment of the present invention, the assignment rule can assign the first variables to the second variables in an unambiguous manner, i.e., at most one second variable is assigned to each first variable by the assignment rule and preferably also vice versa. A set can be understood as a form of combining the individual variables. Preferably, the first and second sets are different sets that do not have a common variable. Preferably, an index is assigned to each of the variables of the first and second sets. All indices of the first and second sets could be regarded as index sets. That is to say, as a set whose elements index the variables of the first or second set. The assignment rule then assigns an index from the second index set to each element of the first index set. The assignment rule accordingly describes which first variable is associated with which second variable and preferably also vice versa. The assignment rule can be in the form of a list or table or the like.

According to an example embodiment of the present invention, the method begins with providing a machine learning system, which was trained, using the assignment rule, to assign the first variables to the second variables according to the assignment rule. The machine learning system may be one or a plurality of decision trees, a neural network, a support vector machine, or the like. It should be noted that, preferably, the assignment rule and the machine learning system are alternately created and trained. The method described in German Patent Application No. DE 10 2021 209 343 is particularly preferably used here.

According to an example embodiment of the present invention, this is followed by ascertaining inaccuracies of the machine learning system, wherein the inaccuracies are ascertained by means of a difference between the second variables predicted by the machine learning system depending on the first variables and the second variables assigned to the first variables according to the assignment rule. The difference is preferably a residual between the prediction of the machine learning system and the assigned second variable. This is followed by ascertaining a covariance matrix depending on the ascertained inaccuracies. This is followed by ascertaining a likelihood matrix, wherein the ascertained inaccuracies are grouped into a vector for this purpose, wherein the transposed vector is multiplied by the inverted covariance matrix and the result thereof is multiplied by the vector. This is followed by normalizing the likelihood matrix by dividing the values/entries of the likelihood matrix by the corresponding column sums. In an optional step, the normalized likelihood matrix can be output. The entries of the likelihood matrix preferably specify a probability of how safely or reliably the j-th first variable assigned to the entry [i,j] and the i-th second variable assigned to this entry would be assigned by the machine learning system, in particular by the assignment rule.

The method makes it possible to substantially probabilistically quantify the (aleatory) uncertainty inherent in the machine learning system, since even a perfect model may have difficulty distinguishing between very similar components/chips. It is thus now possible to ascertain an uncertainty estimate or reliability estimate of the assignment rule via the aleatory uncertainty.

The first and/or second variables may be scalars or vectors, such as a time series, in particular sensor data sensed by a sensor or ascertained indirectly. Preferably, the first and second variables are respectively one or a plurality of measurement results from a measurement or from a plurality of different measurements, which were respectively performed on an object of a plurality of objects. This means that each variable is assigned to one of the objects. The assignment rule can specify which first and second variables are measurement results of the same object. Particularly preferably, the at least one measurement of the objects for the first variables was performed at a first time and the measurement for the second variables were performed at a second time, wherein the second time is after the first time. The second time may, for example, be after the objects have been subjected to a modification or change.

According to an example embodiment of the present invention, it is provided that, when the likelihood matrix is ascertained, the result of the vector matrix vector multiplication is additionally scaled with a specified value, and wherein an exponential function is applied to this scaled result. Preferably, the specified value is less than 1; particularly preferably, the value is 0.5.

This has the advantage that a probabilistic consideration of the uncertainties is now possible. Mathematically, this may be expressed as follows:

$${L}_{ij} = exp ( - \frac{1}{2} {( {y}_{j} - f ( {x}_{i} ) )}^{T} {\sum }^{- 1} ( {y}_{j} - f ( {x}_{i} ) ) )$$

where f(xᵢ) is the prediction of the machine learning system depending on the first variable x, and y describes the second variable, and Σ is the covariance matrix.

Furthermore, according to an example embodiment of the present invention, it is provided that the machine learning system is a regression model which ascertains the second variables depending on the first variables and parameters of the regression model, wherein the parameters of the regression model are adjusted during the training. Preferably, the regression model is a linear regression model.

The regression is used to model relationships between a dependent (often also explained variable) and one or more independent variables (often also explanatory variables). The regression is able to parameterize a more complex function so that this function best represents data according to a particular mathematical criterion. For example, the common method of least squares calculates an unambiguous straight line (or hyperplane) that minimizes the sum of squares of the deviations between the true data and this line (or hyperplane), i.e., the residual sum of squares.

Furthermore, according to an example embodiment of the present invention, it is provided that the first and second variables characterize a product during the production thereof after different production process steps. For example, the second time may be when a production process step has been completed. The product may be any product produced in a manufacturing plant. Preferably, when the product is produced, the traceability to its previous process steps is lost (so-called “bulk material”), for example if it is no longer possible to directly assign the product from the bulk material, e.g., screws, to a production batch. It is possible that the first variables characterize components, in particular component parts, and the second variables characterize final products, wherein the assignment rule describes which component has been processed into which product or which component part has been installed in which product. For example, if the component part in the product can no longer be removed in a non-destructive manner in order to read a serial number. With the present invention, it is then possible to assign the production batch of the component part on the basis of measurements of the product.

The first and second variables may be measurement/test results or other properties of the products, components, etc. The first and second variables preferably differ slightly from one another, e.g., due to manufacturing tolerances, but describe the same measurements/properties of the products, components, etc.

According to an example embodiment of the present invention, it is furthermore provided that the first variables are first test results or measurement results of semiconductor component elements on a wafer and the second variables are second test results or measurement results of the semiconductor component elements after the semiconductor component elements have been cut out of the wafer. Semiconductor component elements may be parts of grown electrical component parts on the wafer, e.g., a transistor group of an integrated circuit. The test results may also refer to the entire semiconductor component. Here, linear regression for the machine learning system has proven to be particularly effective in finding the best assignment rule. This is because linear regression is based on a linear correlation, which is a reasonable assumption for the assignment of test results here. Linear regression is a special case of regression.

In linear regression, a linear function is assumed. That is to say, only correlations in which the dependent variable is a linear combination of the regression coefficients (but not necessarily of the independent variables) are used.

Furthermore, according to an example embodiment of the present invention, it is provided that the first test results are wafer level test results and the second test results are final test results. Preferably, there are fewer final test results than wafer level test results. The tests are, for example, voltage tests and/or contact tests.

Furthermore, according to an example embodiment of the present invention, it is provided that the semiconductor component elements have been produced on a plurality of different wafers.

According to an example embodiment of the present invention, it is furthermore provided that it is ascertained, depending on the assignment rule and the likelihood matrix, which second test result is associated with which first test result, and wherein it is then ascertained, depending on the associated first test result, at which position the semiconductor component was arranged within a wafer. This allows a position reconstruction, which makes it possible for the first time to unambiguously trace the semiconductor components from the final production process steps of the semiconductor production to previous process steps. Preferably, the position reconstruction is visualized along with the respectively associated entries of the likelihood matrix. This has the advantage that a user can quickly visually understand which position reconstructions could be less reliable.

On the basis of the assignment rule and the likelihood matrix, more accurate traceability can be achieved when restoring the traceability between wafer levels and final test values, since the likelihood matrix contains a quantification of the uncertainty of the assignment rule, which allows, for example, to use only safe assignments for tracing. An assignment is safe if, for example, a corresponding entry of the likelihood matrix for the respective assignment is greater than a specified value.

Advantageously, the likelihood matrix can also be used to answer probabilistic questions. For example, the likelihood matrix can be used to estimate how many similar second variables (for example FT test results) exist given similar probability distributions along columns of the likelihood matrix, or how likely chip A is assigned to chip B, or how likely a WLT value range is measured given a FT test result.

For example, the likelihood matrix can be used to estimate how likely it is to have a particular chip marked as missing, wherein a row sum of the likelihood matrix is calculated for this purpose. Since this sum may also be greater than 1, a cut-off takes place at 1. The lower the sum for a first variable (e.g., a chip) of the associated row is, the higher is the probability that it is marked as missing.

For example, the likelihood matrix can also be used to estimate how reliable the assignment is, in particular between wafer levels and final test results. Each column in the likelihood matrix specifies a probability distribution of the assignment of a FT test result. The more “concentrated” these distributions are, the lower is the uncertainty. For example, a highest value (=the highest probability) can be calculated by the 0.95 quantile in order to ascertain a measure of the reliability.

Such probabilistic statements on the basis of the likelihood matrix help to better understand the model and the production process and can lead to better process control. In addition, threshold values for using particular assignments for upstream tasks can be defined (e.g., selecting only assignments with a high probability).

According to an example embodiment of the present invention, it is furthermore provided that, in addition to the positions, further variables characterizing the wafer and/or the semiconductor components on the wafer are ascertained along with respectively assigned test results, wherein these data are combined into a further training data set, wherein, depending on the further training data set, a further machine learning system is trained to predict the second test results.

The advantage here is that the assignment can be used to create a further training data set in order to train a further machine learning system to predict properties of a packaged semiconductor element at an early stage of the production process. This significantly reduces the time until deviations in the process parameters are detected. In particular for parameters that can only be correctly evaluated during final tests (e.g., RDSon).

A further advantage here is that the assignment can also be used to train a further machine learning system that actively identifies defective semiconductor chips. This saves process resources and reduces waste.

According to an example embodiment of the present invention, it is furthermore provided that the semiconductor component elements are power MOSFETs.

In further aspects, the present invention relates to a device and to a computer program, which are each configured to perform the above methods of the present invention, and to a machine-readable storage medium in which this computer program is stored.

Example embodiments of the present invention are explained in greater detail below with reference to the figures.

### BRIEF DESCRIPTION OF THE DRAWINGS

FIG. 1 schematically shows a packaging process, according to an example embodiment of the present invention.

FIG. 2 schematically shows an exemplary embodiment of a flowchart of the present invention.

### DETAILED DESCRIPTION OF EXAMPLE EMBODIMENTS

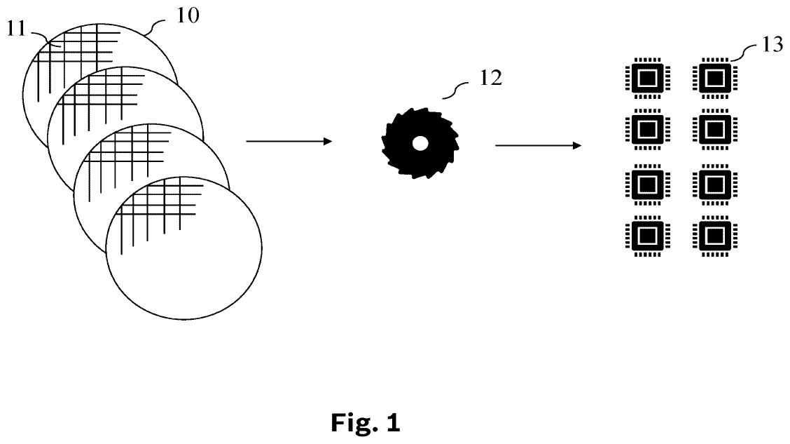

In the packaging process of semiconductor components or semiconductor elements, the traceability of the elements to their original wafer and their original position on the respective wafer is usually lost. This is because, after cutting out the semiconductor elements, mixing of the individual semiconductor elements may occur, whereby the position of the component parts on the wafer is lost if they do not have an unambiguous marking. This is schematically shown in FIG. 1. The wafers 10 respectively have a plurality of semiconductor components or semiconductor elements 11. At this stage, each semiconductor element 11 has a known position on the wafers 10. At this stage, the semiconductor elements 11 are usually subjected to a plurality of tests, which are also referred to as the wafer level test. This is followed by cutting the wafers 10 so that the semiconductor elements 11 are separated from one another. Cutting may take place by means of a saw 12 or by means of a laser. Finally, the cut semiconductor elements are packaged, for example installed in microcontrollers 13. No later than at this stage is the information lost as to the wafer 10 and the position within the wafer 10 on/at which the semiconductor element was originally positioned. Usually, the microcontrollers 13 with the semiconductor elements 11 are again subjected to a plurality of tests, which are also referred to as the final test. However, since mixing took place as a result of cutting the wafers 10, it cannot be readily unambiguously traced on which wafer 10 the respective semiconductor element 11 of the microcontrollers 13 was arranged and which wafer level test corresponds to which final test, i.e., are the test results of the same semiconductor element. The semiconductor elements may be microelectronic assemblies, such as integrated circuits (hereinafter also referred to as a chip), sensors, or the like.

It is important to make traceability after the packaging process in a semiconductor production process possible. Such an assignment makes further contributions, such as better process control or early prediction of final chip properties, possible. Moreover, the cause analysis of the deviations measured in the final test at the chip level can be expanded to the processes in the wafer production. This in turn makes a much deeper understanding of the processes possible and leads to better process control and thus better quality.

German Patent Application No. DE 10 2021 209 343 describes an assignment algorithm for ascertaining an assignment rule, which algorithm consists of an alternating sequence of optimizing regression parameters (when regressing from wafer level test to final test data) and subsequently optimizing the assignment of test partners. The current assignment of the final test chips is used as a regression label in each iteration.

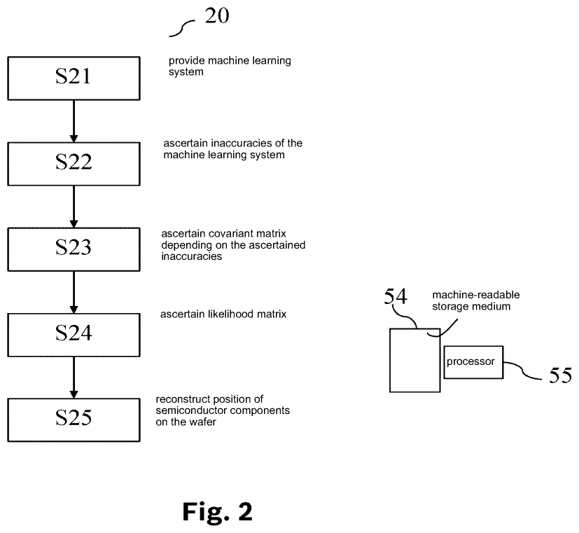

FIG. 2 schematically shows a flowchart 20 of a method for estimating, in particular ascertaining, an uncertainty of the assignment rule. The assignment rule can assign test results of the final test to the respectively corresponding wafer level test results. After the method has been completed, there should be an assignment rule as well as an estimate of the uncertainty of the assignment rule, which assigns the associated test results of the wafer level test to the final tests.

The method starts with step S21. In this step, a machine learning system is provided, which was trained, on the basis of the assignment rule, to assign the first variables to the second variables according to the assignment rule.

This is followed by ascertaining (S22) inaccuracies A of the machine learning system, wherein the inaccuracies are ascertained by means of a difference between the second variables predicted by the machine learning system depending on the first variables and the second variables assigned to the first variables according to the assignment rule.

This is followed by ascertaining (S23) a covariance matrix Z depending on the ascertained inaccuracies.

This is followed by ascertaining (S24) a likelihood matrix L. The latter can be calculated using the following formula:

$$L = exp ( - \frac{1}{2} {Δ}^{T} {\sum }^{- 1} Δ )$$

This is finally followed by normalizing (S25) the likelihood matrix L.

In a step optionally following step S25, the position of the semiconductor components 11 on the wafer 10 is reconstructed by means of the assignment rule and the likelihood matrix. In this case, the assignment rule can be used to determine the WLT test results backward starting from the FT test results, wherein it is decided, depending on the likelihood matrix, whether the assignment by the assignment rule is reliable. Since the position within the wafer at which the respective test has been performed is usually stored in addition to the WLT test results, it can thus be reconstructed where exactly the corresponding semiconductor element was produced on the wafer.

It is possible that a control signal for controlling a physical system, such as a computer-controlled machine, such as a manufacturing machine, in particular machining machines for the wafers, are controlled depending on a position reconstruction. For example, if the FT test results are not optimal, the control signal can adjust a previous production step accordingly in order to obtain better FT test results later.

The steps of a device for performing the method according to FIG. 2 can be stored, implemented as a computer program, on a machine-readable storage medium 54 and can be executed by a processor 55.

1-11. (canceled)

12. A method for estimating an uncertainty of an assignment rule that assigns first variables from a first set of first variables to second variables from a second set of second variables, comprising the following steps:
providing a machine learning system, which is trained, based on the assignment rule, to assign the first variables to the second variables according to the assignment rule;
ascertaining inaccuracies of the machine learning system, wherein the inaccuracies are ascertained using a difference between second variables predicted by the machine learning system, the second variables being predicted depending on the first variables, and the second variables assigned to the first variables according to the assignment rule;
ascertaining a covariance matrix depending on the ascertained inaccuracies;
ascertaining a likelihood matrix of the uncertainties of the assignment rule, wherein the ascertained inaccuracies are grouped into a vector, wherein the vector, transposed, is multiplied by the covariance matrix, inverted, and a result thereof is multiplied by the vector; and
normalizing the likelihood matrix.

13. The method according to claim 12, wherein, when the likelihood matrix is ascertained, a result of the vector matrix vector multiplication is additionally scaled with a specified value, and wherein an exponential function is applied to the scaled result.

14. The method according to claim 12, wherein the machine learning system is a regression model which ascertains the second variables depending on the first variables and parameters of the regression model.

15. The method according to claim 12, wherein the first and second variables characterize products during production of the products after different production process steps, wherein the assignment rule characterizes which of the first and second variables of the first and second sets characterize a same product.

16. The method according to claim 12, wherein the first variables are first test results of semiconductor component elements on a wafer, and the second variables are second test results of the semiconductor component elements after the semiconductor component elements have been cut out of the wafer, wherein the assignment rule characterizes which first and second test results originate from the same semiconductor component element.

17. The method according to claim 16, wherein the first test results are wafer level test results and the second test results are final test results.

18. The method according to claim 16, wherein the semiconductor component elements have been produced on a plurality of different wafers.

19. The method according to claim 16, wherein it is ascertained, depending on the assignment rule and the normalized likelihood matrix, which second test result is associated with which first test result, and wherein it is then ascertained, depending on the associated first test result, at which position the semiconductor component element was arranged within a wafer.

20. A device configured to estimate an uncertainty of an assignment rule that assigns first variables from a first set of first variables to second variables from a second set of second variables, the device configured to:
provide a machine learning system, which is trained, based on the assignment rule, to assign the first variables to the second variables according to the assignment rule;
ascertain inaccuracies of the machine learning system, wherein the inaccuracies are ascertained using a difference between second variables predicted by the machine learning system, the second variables being predicted depending on the first variables, and the second variables assigned to the first variables according to the assignment rule;
ascertain a covariance matrix depending on the ascertained inaccuracies;
ascertain a likelihood matrix of the uncertainties of the assignment rule, wherein the ascertained inaccuracies are grouped into a vector, wherein the vector, transposed, is multiplied by the covariance matrix, inverted, and a result thereof is multiplied by the vector; and
normalize the likelihood matrix.

21. A non-transitory machine-readable storage medium on which is stored a computer program for estimating an uncertainty of an assignment rule that assigns first variables from a first set of first variables to second variables from a second set of second variables, the computer program, when executed by a computer, causing the computer to perform the following steps:
providing a machine learning system, which is trained, based on the assignment rule, to assign the first variables to the second variables according to the assignment rule;
ascertaining inaccuracies of the machine learning system, wherein the inaccuracies are ascertained using a difference between second variables predicted by the machine learning system, the second variables being predicted depending on the first variables, and the second variables assigned to the first variables according to the assignment rule;
ascertaining a covariance matrix depending on the ascertained inaccuracies;
ascertaining a likelihood matrix of the uncertainties of the assignment rule, wherein the ascertained inaccuracies are grouped into a vector, wherein the vector, transposed, is multiplied by the covariance matrix, inverted, and a result thereof is multiplied by the vector; and
normalizing the likelihood matrix.
